(19) United States
(12) Patent Application Publication
(10) Pub. No.: US 2024/0339812 A1
(43) Pub. Date: Oct. 10, 2024

(54) DRIVING DEVICE, DRIVING METHOD, AND LIGHT EMITTING DEVICE

(71) Applicant: SONY SEMICONDUCTOR SOLUTIONS CORPORATION, KANAGAWA (JP)

(72) Inventors: SUGURU KAMADA, KUMAMOTO (JP); KOUJI MORI, KUMAMOTO (JP)

(21) Appl. No.: 18/294,061

(22) PCT Filed: Mar. 10, 2022
(86) PCT No.: PCT/JP2022/010593

§ 371 Date: Jan. 31, 2024

(30) Foreign Application Priority Data
Sep. 8, 2021 (JP) 2021-146272

(51) Int. Cl. H01S 5/0683; H05B 45/12

(52) U.S. Cl. CPC H01S 5/0683; H05B 45/12

(57) ABSTRACT

The present invention stabilizes a control signal for an element that supplies a drive current to a light-emitting element. According to the present invention, a drive device includes a switch element, a current-limiting element, a current-limiting element control unit, and a detection unit. The switch element is connected in series with a light-emitting element and transmits a drive current during a light-emitting period. The current-limiting element is connected in series with the switch element and limits the drive current to a set current value. The current-limiting element control unit generates a current control signal corresponding to the set current value and supplies the current control signal to a control terminal of the current limiting element. The detection unit detects a change in the current control signal during the light-emitting period and causes the current-limiting element control unit to adjust the current control signal.

### FIELD

The present disclosure relates to a driving device, a driving method, and a light emitting device.

### BACKGROUND

A driving device that appropriately drives a light emitting element used as a light source has been proposed. For example, there has been proposed a driving device including a light receiving element that receives a part of output light from a light emitting element and setting a target current for setting the output light to a desired intensity. The driving device controls a driving current of the light emitting element based on the set target current. The light emitting element of the driving device is driven by a MOS transistor that supplies a constant current to the light emitting element. In a period in which the light emitting element is caused to emit light, a gate voltage corresponding to the target current is applied to the MOS transistor to cause a driving current to flow through the light emitting element, and a light emission intensity is controlled to a desired one.

### CITATION LIST

### Patent Literature

Patent Literature 1: JP 2019 041201 A

### SUMMARY

### Technical Problem

However, in the above-described conventional technology, there is a problem that the light emission intensity changes in a case where the gate voltage of the MOS transistor that supplies the driving current to the light emitting element changes.

Therefore, the present disclosure proposes a driving device, a driving method, and a light emitting device that stabilize a control signal of an element that supplies a driving current to a light emitting element.

### Solution to Problem

A driving device according to the present disclosure includes: a switch element that is connected in series with a light emitting element and causes a driving current to flow in a light emission period; a current limiting element that is connected in series to the switch element and that limits the driving current to a set current value; a current limiting element control unit that generates a current control signal corresponding to the set current value and supplies the current control signal to a control terminal of the current limiting element; and a detection unit that detects a change in the current control signal in the light emission period and causes the current limiting element control unit to adjust the current control signal.

### BRIEF DESCRIPTION OF DRAWINGS

FIG. 1 is a diagram illustrating a configuration example of a light emitting device according to an embodiment of the present disclosure.

FIG. 2 is a diagram illustrating a configuration example of a light emission control unit and a control signal output unit according to an embodiment of the present disclosure.

FIG. 3 is a diagram illustrating a configuration example of a detection unit according to an embodiment of the present disclosure.

FIG. 4 is a diagram illustrating an example of adjustment of a current control signal according to an embodiment of the present disclosure.

FIG. 5 is a diagram illustrating an example of a driving method according to an embodiment of the present disclosure.

FIG. 6 is a diagram illustrating a configuration example of a distance measuring device to which the technology according to the present disclosure can be applied.

### DESCRIPTION OF EMBODIMENTS

Hereinafter, embodiments of the present disclosure will be described in detail with reference to the drawings. The description will be given in the following order. Note that in the following embodiments, the same parts are denoted by the same reference numerals, and redundant description will be omitted.
1. Embodiments
2. Example of Application to Distance Measuring Device

### 1. Embodiments

### [Configuration of Light Emitting Device]

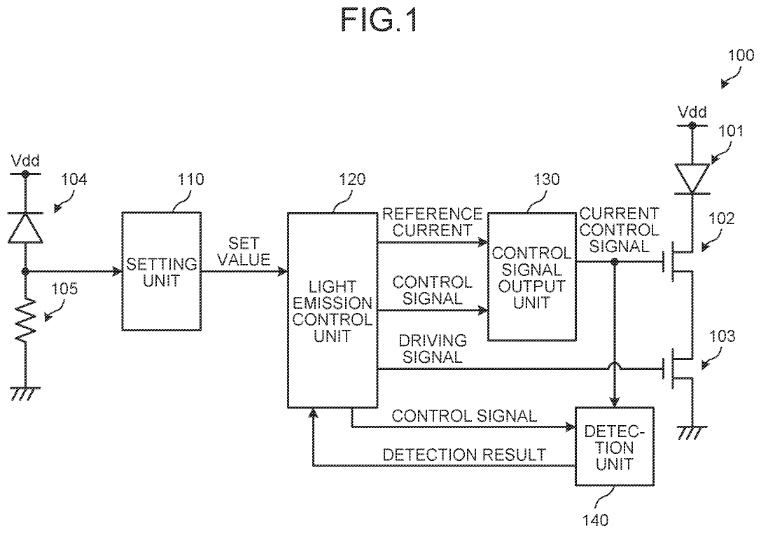

FIG. 1 is a diagram illustrating a configuration example of a light emitting device according to an embodiment of the present disclosure. The drawing is a diagram representing the configuration example of a light emitting device 100. The light emitting device 100 is a device that includes a light emitting element and a driving circuit for the light emitting element and applies light. The light emitting device 100 includes a light emitting element 101, a switch element 103, a current limiting element 102, a light receiving element 104, a resistor 105, a setting unit 110, a light emission control unit 120, a control signal output unit 130, and a detection unit 140.

The light emitting element 101 is an element that outputs light. For example, a laser diode can be used as the light emitting element 101. In the light emitting element 101 in the drawing, an anode is connected to a power supply line Vdd that supplies power, and a cathode is connected to a drain of the current limiting element 102.

The current limiting element 102 is connected in series with the light emitting element 101 and limits a driving current flowing through the light emitting element 101 in a light emission period to a set current value. Here, the driving current is a current that causes the light emitting element 101 to emit light with a desired intensity. In addition, the current limiting element 102 is an element that drives the light emitting element 101 at a constant current. For example, a MOS transistor can be applied to the current limiting element 102.

The switch element 103 is an element that causes the driving current to flow in the light emission period. In the switch element 103 in the drawing, a drain is connected to a source of the current limiting element 102, and a source is grounded. In this manner, the switch element 103 is connected in series with the light emitting element 101 via the current limiting element 102. For example, a MOS transistor can be applied to the switch element 103.

The light receiving element 104 is an element that receives light from the light emitting element 101 and outputs a received light current. In the light receiving element 104 in the drawing, a cathode is connected to the power supply line Vdd, and an anode is connected to the resistor 105.

The resistor 105 is an element that is connected in series with the light receiving element 104 and generates a voltage corresponding to the received light current of the light receiving element 104.

The setting unit 110 sets a driving current value of the light emitting element 101 based on the output of the light receiving element 104. The set value of the driving current is output to the light emission control unit 120.

The light emission control unit 120 generates a current control signal corresponding to the set value of the driving current and supplies the current control signal to a control terminal of the current limiting element 102. In a case where a MOS transistor is used for the current limiting element 102, a gate serves as the control terminal. The light emission control unit 120 in the drawing supplies the current control signal to the current limiting element 102 via the control signal output unit 130. The light emission control unit 120 outputs a reference current of a current mirror circuit described later to the control signal output unit 130 as the current control signal. In addition, the light emission control unit 120 further outputs a control signal for controlling the control signal output unit 130. In addition, the light emission control unit 120 generates and outputs a driving signal of the switch element 103. In addition, the light emission control unit 120 generates and outputs a control signal of the detection unit 140. Details of the configuration of the light emission control unit 120 will be described later. Note that the light emission control unit 120 is an example of a current limiting element control unit described in the claims.

The control signal output unit 130 constitutes the current mirror circuit with the current limiting element 102, and supplies a gate voltage of the current mirror circuit to the current limiting element 102 as the current control signal.

The detection unit 140 detects a change in the current control signal in the light emission period. The detection unit 140 in the drawing detects a change in the gate voltage output from the control signal output unit 130. A detection result of the detection unit 140 is output to the light emission control unit 120. The light emission control unit 120 adjusts the current control signal based on the detection result.

Note that the circuit of the setting unit 110, the light emission control unit 120, the control signal output unit 130, the detection unit 140, the switch element 103, and the current limiting element 102 in the drawing is an example of a driving device described in the claims.

### [Configuration of Light Emission Control Unit and Control Signal Output Unit]

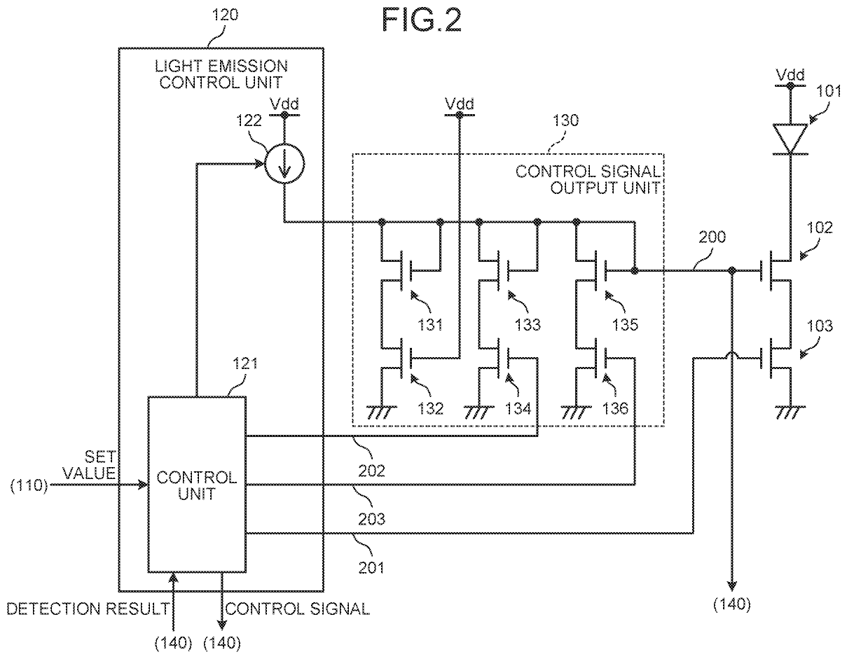

FIG. 2 is a diagram illustrating a configuration example of the light emission control unit and the control signal output unit according to an embodiment of the present disclosure. The drawing is a circuit diagram representing the configuration example of the light emission control unit 120 and the control signal output unit 130.

The light emission control unit 120 in the drawing includes a control unit 121 and a constant current source 122.

The constant current source 122 generates and outputs the reference current of the current mirror circuit based on the control of the control unit 121. The constant current source 122 in the drawing outputs the reference current of a source current to a signal line 200.

The control unit 121 sets the reference current of the constant current source 122 based on the set value of the driving current input from the setting unit 110. In addition, the control unit 121 generates and outputs the control signals of the control signal output unit 130 and the switch element 103. As represented in the drawing, the control signal of the control signal output unit 130 is transmitted by signal lines 202 and 203. In addition, the control signal of the switch element 103 is transmitted by a signal line 201.

As described later, the control unit 121 further generates and outputs the control signal of the detection unit 140. In addition, the control unit 121 further performs adjustment of the above-described reference current and adjustment of the control signal to the control signal output unit 130 based on the detection result of the detection unit 140.

The control signal output unit 130 includes MOS transistors 131 to 136. As the MOS transistors 131 to 136, n-channel MOS transistors can be used. A drain and a gate of the MOS transistor 131, a drain and a gate of the MOS transistor 133, and a drain and a gate of the MOS transistor 135 are commonly connected to the signal line 200. A source of the MOS transistor 131 is connected to a drain of the MOS transistor 132. A gate of the MOS transistor 132 is connected to the power supply line Vdd, and a source is grounded. A source of the MOS transistor 133 is connected to a drain of the MOS transistor 134. A gate of the MOS transistor 134 is connected to the signal line 202, and a source is grounded. A source of the MOS transistor 135 is connected to a drain of the MOS transistor 136. A gate of the MOS transistor 136 is connected to the signal line 203, and a source is grounded. In addition, the signal line 200 is connected to a gate of the current limiting element 102 and the detection unit 140.

The MOS transistors 131, 133, and 135 connected in parallel and the current limiting element 102 constitute the current mirror circuit. A current corresponding to the reference current flowing through the MOS transistors 131, 133, and 135 flows through the current limiting element 102. This current becomes the driving current of the light emitting element 101. The MOS transistors 132, 134, and 136 are switches that respectively connect the MOS transistors 131, 133, and 135 to the current mirror circuit. A current mirror ratio of the current mirror circuit can be changed by switching between conduction and non-conduction of the MOS transistors 131, 133, and 135. Note that in the drawing, the MOS transistor 132 is always in a conductive state.

The current mirror ratio in a case where the MOS transistor 132 is conductive and the MOS transistors 134 and 136 are non-conductive can be set to, for example, 1:200. In this case, the current mirror ratio is the highest. A driving current 200 times the reference current flows through the current limiting element 102. The current mirror ratio in a case where the MOS transistors 131, 133, and 135 are in the conductive state can be set to, for example, 3:200. The current mirror ratio can be changed to a desired value by adjusting the channel width and channel length of the MOS transistors 131, 133, and 135.

In this manner, the control unit 121 can adjust the driving current of the current limiting element 102 by adjusting the reference current and the control signal of the control signal output unit 130.

### [Configuration of Detection Unit]

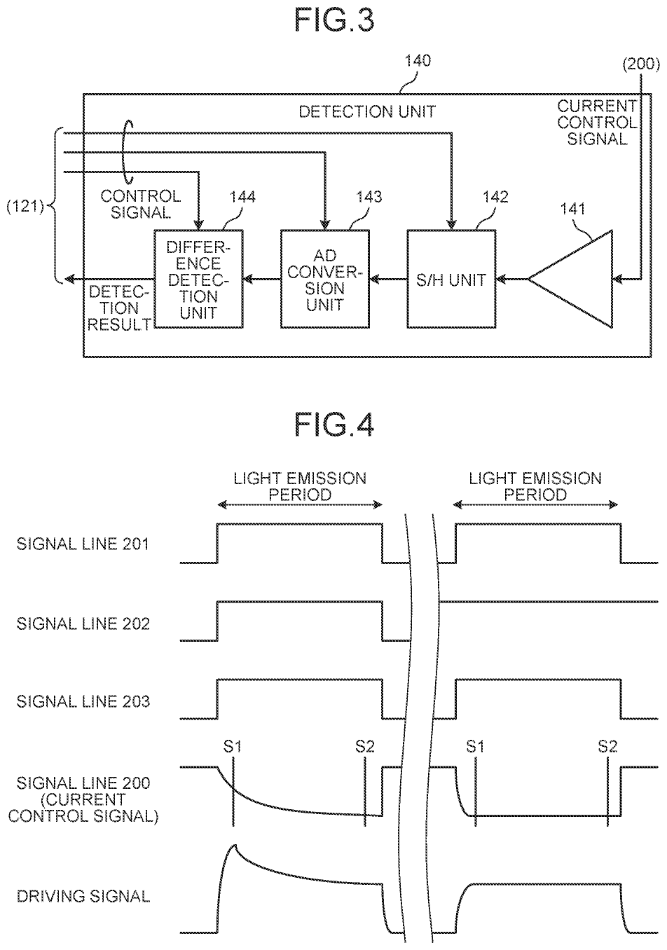

FIG. 3 is a diagram illustrating a configuration example of the detection unit according to an embodiment of the present disclosure. The drawing is a block diagram representing the configuration example of the detection unit 140. The detection unit 140 includes an amplifier 141, an S/H unit 142, an AD conversion unit 143, and a difference detection unit 144.

The amplifier 141 is connected at an input terminal to the signal line 200 described above and amplifies the current limiting signal. The amplifier 141 is used as a buffer. An output of the amplifier 141 is connected to the S/H unit 142.

The S/H unit 142 captures and holds the current control signal amplified by the amplifier 141 at a predetermined timing. The held current control signal is output to the AD conversion unit 143. Note that the S/H unit 142 can capture and hold the current control signal twice in the light emission period.

The AD conversion unit 143 converts the current control signal held by the S/H unit 142 into a digital signal. The converted digital current control signal is output to the difference detection unit 144.

The difference detection unit 144 detects a difference between the two current control signals held by the S/H unit 142. This difference corresponds to a change in the current control signal in the light emission period. The detected difference is output to the control unit 121 as a detection result of the detection unit 140.

The control unit 121 adjusts the reference current and the control signal of the control signal output unit 130 so as to reduce the difference between the current control signals, which is the detection result of the detection unit 140. The adjustment of the control signal of the control signal output unit 130 corresponds to, for example, adjustment of the timing and pulse width of the control signal.

### [Adjustment of Current Control Signal]

FIG. 4 is a diagram illustrating an example of adjustment of the current control signal according to an embodiment of the present disclosure. The drawing is a diagram representing an example of adjustment of the current control signal by the control unit 121. “Signal line 201”, “signal line 202”, “signal line 203”, and “signal line 200” in the drawing respectively represent the binarized waveforms of the control signals of the signal lines 201, 202, 203, and 200 in FIG. 2. The portion of the value “1” of the waveforms represents an on-voltage of the MOS transistor. This on-voltage is a voltage exceeding a threshold of a gate-drain voltage Vgs that brings the MOS transistor into the conductive state. In addition, the portion of the value “0” represents an off-voltage of the MOS transistor. In addition, “signal line 200” represents the waveform of the current control signal of the signal line 200. This corresponds to the gate voltage of the current limiting element 102. “Driving current” represents the waveform of the driving current of the light emitting element 101.

In the drawing, the current control signal has a relatively high voltage in a non-light emission period. This is because the MOS transistor 132 in FIG. 2 is conductive. By increasing the gate voltage of the current limiting element 102 in the non-light emission period, it is possible to reduce a decrease in the gate voltage of the current limiting element 102 due to a mirror effect when shifting to the light emission period. The gate voltage of the current limiting element 102 can be adjusted to, for example, 1.3 V in the non-light emission period and 1.0 in the light emission period.

The left side of the drawing represents an example of a case where control is performed to simultaneously turn on the switch element 103, the MOS transistor 134, and the MOS transistor 136 in FIG. 2 in the light emission period. The voltage (current control signal) of the signal line 200 has a waveform in which the voltage gradually decreases in the light emission period. In this case, a sag is generated in the driving current, and the light emission intensity of the light emitting element 101 fluctuates.

Note that “S1” and “S2” in the drawing represent the timing at which the current control signal is captured by the detection unit 140 described in FIG. 3. The detection unit 140 detects a difference between the current control signals at “S1” and “S2”, and outputs the difference to the control unit 121. In this manner, the detection unit 140 can detect the difference between the current control signals at an initial stage and an end stage of the light emission period.

The right side of the drawing represents an example of a case where the on-voltage is always applied to the signal line 202 to bring the MOS transistor 134 into the conductive state. The current control signal of the current limiting element 102 can have a flat waveform, and fluctuations in the driving current can be reduced.

### [Driving Method]

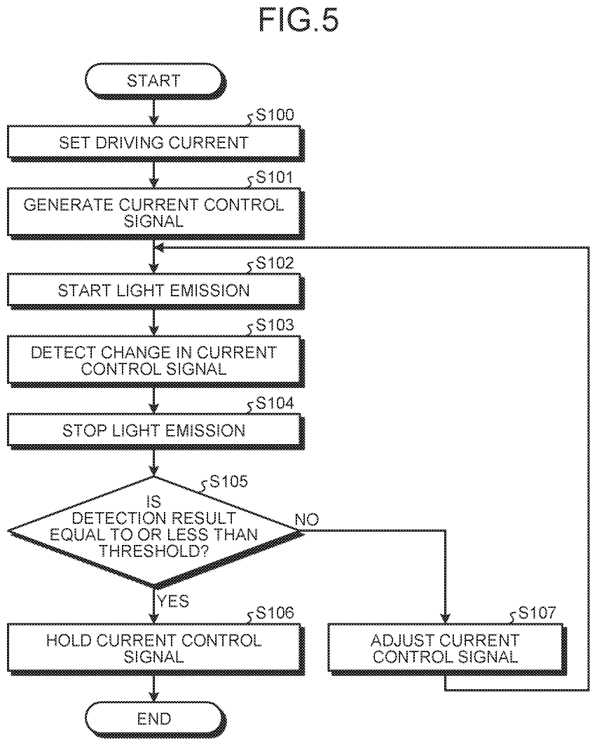

FIG. 5 is a diagram illustrating an example of a driving method according to an embodiment of the present disclosure. The drawing is a flowchart representing an example of the driving method for the light emitting device 100. First, the setting unit 110 sets the driving current based on the received light current (Step S100). Next, the control unit 121 generates the current control signal based on the set current value (Step S101). Next, the control unit 121 outputs the control signals of the current limiting element 102 and the switch element 103 to cause the starting of light emission of the light emitting element 101 (Step S102). Next, the detection unit 140 detects a change in the current control signal (Step S103). This can be performed by detecting a difference between the current control signals. Next, the control unit 121 causes the stopping of light emission of the light emitting element 101 (Step S104). Next, the control unit 121 compares the detection result from the detection unit 140 with a predetermined threshold (Step S105). As a result, in a case where the detection result is equal to or less than the threshold (Yes in Step S105), the process proceeds to the process of Step S106. On the other hand, in a case where the detection result is not equal to or less than the threshold (No in Step S105), the current control signal is adjusted (Step S107), and the process proceeds to the process of Step S102.

In Step S106, the control unit 121 holds the current control signal (Step S106). This can be performed by storing the settings of the reference current for outputting the current control signal and the control signal of the control signal output unit 130.

In this manner, the light emitting device 100 of the embodiment of the present disclosure detects a change in the current control signal of the current limiting element 102 in the light emission period, and adjusts the current control signal based on the detection result. As a result, the current control signal can be stabilized, and fluctuations in the light emission intensity of the light emitting element 101 can be reduced.

### 2. Example of Application to Distance Measuring Device

The light emitting device 100 of the above-described embodiment can be applied to various products. An example of applying the light emitting device 100 to a distance measuring device will be described.

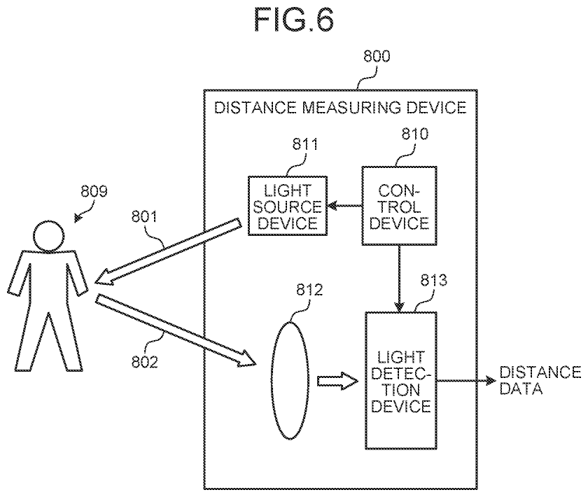

FIG. 6 is a diagram illustrating a configuration example of a distance measuring device to which the technology according to the present disclosure can be applied. The drawing is a block diagram representing the configuration example of a distance measuring device 800. The distance measuring device 800 includes a light detection device 813, a control device 810, a light source device 811, and an imaging lens 812. The distance measuring device 800 performs distance measurement to measure a distance to an object. An object 809 is further illustrated in the drawing.

The light source device 811 applies light. The light source device 811 applies output light 801 to the object 809 in distance measurement. As the light source device 811, for example, a light emitting diode that outputs infrared light can be used.

The imaging lens 812 is a lens that condenses light from the object 809 on the light detection device 813. The imaging lens 812 in the drawing condenses reflected light 802, which is the output light 801 reflected by the object 809, on the light detection device 813.

The light detection device 813 detects the reflected light 802 from the object 809 and measures the distance to the object 809. The light detection device 813 includes a sensor that detects the reflected light 802 and a processing circuit that performs a distance measuring process. This distance measuring process is a process of measuring time from the outputting of the output light 801 by the light source device 811 to the detection of the reflected light 802, and measuring the distance to the object 809 based on the measured time from the outputting of the output light 801 to the detection of the reflected light 802. The measured distance to the object 809 is output to an external device as distance data.

The control device 810 controls the entire distance measuring device 800. In distance measurement, the control device 810 performs control to cause the light source device 811 to output the output light 801, and performs control to cause the light detection device 813 to start time measurement and perform distance measurement.

To the light source device 811 in the drawing, the light emitting device 100 in FIG. 1 can be applied.

Note that the effects described in the present specification are merely examples and are not limited, and other effects may be provided.

Note that the present technology can also have the following configurations.

(1)

A driving device comprising:
a switch element that is connected in series with a light emitting element and causes a driving current to flow in a light emission period;
a current limiting element that is connected in series to the switch element and that limits the driving current to a set current value;
a current limiting element control unit that generates a current control signal corresponding to the set current value and supplies the current control signal to a control terminal of the current limiting element; and
a detection unit that detects a change in the current control signal in the light emission period and causes the current limiting element control unit to adjust the current control signal.
   (2) The driving device according to the above (1), wherein the current limiting element includes a MOS transistor having a gate as the control terminal.
   (3)

The driving device according to the above (2), further comprising
a control signal output unit that constitutes a current mirror circuit with the current limiting element, wherein
the control signal output unit supplies a gate voltage of the current mirror circuit to the current limiting element as the current control signal, and
the current limiting element control unit supplies a reference current in the current mirror circuit corresponding to the set current value to the control signal output unit and adjusts the reference current based on a detection result of the detection unit.
   (4)

The driving device according to the above (3), wherein the current limiting element control unit further adjusts a current mirror ratio of the control signal output unit based on the detection result of the detection unit.

(5)

The driving device according to the above (4), wherein
the control signal output unit includes a plurality of MOS transistors that shunts the reference current, and
the current limiting element control unit adjusts the current mirror ratio by switching between conduction and non-conduction of the plurality of MOS transistors of the control signal output unit.
   (6)

The driving device according to any one of the above (1) to (5), wherein the detection unit detects a difference between the current control signals at an initial stage and an end stage of the light emission period as a change in the current control signal.

(7)

The driving device according to any one of the above (1) to (6), further comprising a setting unit that sets a current value of the light emitting element based on an output of a light receiving element, and supplies the set current value to the current limiting element control unit, the light receiving element receiving light from the light emitting element.

(8)

A driving method comprising:
causing a driving current to flow through a switch element connected in series with a light emitting element in a light emission period;
generating a current control signal corresponding to a set current value;
supplying the current control signal to a control terminal of a current limiting element, the current limiting element being connected in series to the switch element and limiting the driving current to a set current value; and
detecting a change in the current control signal in the light emission period and adjusting the current limiting signal.
   (9)

A light emitting device comprising:
a light emitting element;
a current setting unit that sets a current value of the light emitting element based on an output of a light receiving element, the light receiving element receiving light from the light emitting element;
a switch element that is connected in series with the light emitting element and causes a driving current to flow in a light emission period;
a current limiting element that is connected in series to the switch element and limits the driving current to the set current value;
a current limiting element control unit that generates current control signal corresponding to the set current value and supplies the current control signal to a control terminal of the current limiting element; and
a detection unit that detects a change in the current control signal in the light emission period and causes the current limiting element control unit to adjust the current control signal.

### REFERENCE SIGNS LIST

100 LIGHT EMITTING DEVICE
101 LIGHT EMITTING ELEMENT
102 CURRENT LIMITING ELEMENT
103 SWITCH ELEMENT
104 LIGHT RECEIVING ELEMENT
110 SETTING UNIT
120 LIGHT EMISSION CONTROL UNIT
121 CONTROL UNIT
130 CONTROL SIGNAL OUTPUT UNIT
131 to 136 MOS TRANSISTOR
140 DETECTION UNIT
144 DIFFERENCE DETECTION UNIT
800 DISTANCE MEASURING DEVICE

1. A driving device comprising:
a switch element that is connected in series with a light emitting element and causes a driving current to flow in a light emission period;
a current limiting element that is connected in series to the switch element and that limits the driving current to a set current value;
a current limiting element control unit that generates a current control signal corresponding to the set current value and supplies the current control signal to a control terminal of the current limiting element; and
a detection unit that detects a change in the current control signal in the light emission period and causes the current limiting element control unit to adjust the current control signal.

2. The driving device according to claim 1, wherein the current limiting element includes a MOS transistor having a gate as the control terminal.

3. The driving device according to claim 2, further comprising
a control signal output unit that constitutes a current mirror circuit with the current limiting element, wherein
the control signal output unit supplies a gate voltage of the current mirror circuit to the current limiting element as the current control signal, and
the current limiting element control unit supplies a reference current in the current mirror circuit corresponding to the set current value to the control signal output unit and adjusts the reference current based on a detection result of the detection unit.

4. The driving device according to claim 3, wherein the current limiting element control unit further adjusts a current mirror ratio of the control signal output unit based on the detection result of the detection unit.

5. The driving device according to claim 4, wherein
the control signal output unit includes a plurality of MOS transistors that shunts the reference current, and
the current limiting element control unit adjusts the current mirror ratio by switching between conduction and non-conduction of the plurality of MOS transistors of the control signal output unit.

6. The driving device according to claim 1, wherein the detection unit detects a difference between the current control signals at an initial stage and an end stage of the light emission period as a change in the current control signal.

7. The driving device according to claim 1, further comprising a setting unit that sets a current value of the light emitting element based on an output of a light receiving element, and supplies the set current value to the current limiting element control unit, the light receiving element receiving light from the light emitting element.

8. A driving method comprising:
causing a driving current to flow through a switch element connected in series with a light emitting element in a light emission period;
generating a current control signal corresponding to a set current value;
supplying the current control signal to a control terminal of a current limiting element, the current limiting element being connected in series to the switch element and limiting the driving current to a set current value; and
detecting a change in the current control signal in the light emission period and adjusting the current control signal.

9. A light emitting device comprising:
a light emitting element;
a current setting unit that sets a current value of the light emitting element based on an output of a light receiving element, the light receiving element receiving light from the light emitting element;
a switch element that is connected in series with the light emitting element and causes a driving current to flow in a light emission period;
a current limiting element that is connected in series to the switch element and limits the driving current to the set current value;
a current limiting element control unit that generates current control signal corresponding to the set current value and supplies the current control signal to a control terminal of the current limiting element; and
a detection unit that detects a change in the current control signal in the light emission period and causes the current limiting element control unit to adjust the current control signal.
